(19) United States
(12) Patent Application Publication
(10) Pub. No.: US 2015/0000964 A1
(43) Pub. Date: Jan. 1, 2015

(54) PRINTED CIRCUIT BOARD FOR PREVENTING EDGE-BOARD COMPONENTS FROM BEING SHORT-CIRCUITED

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAI-DONG TANG, Shenzhen (CN)

(73) Assignees: HON HAI PRECISION INDUSTRY CO., LTD., New Taipei (TW); HONG FU JIN PRECISION INDSUTRY (ShenZhen) CO., LTD., Shenzhen (CN)

(21) Appl. No.: 14/102,684

(22) Filed: Dec. 11, 2013

(30) Foreign Application Priority Data
Jun. 28, 2013 (CN) 2013102686105

(51) Int. Cl. H05K 1/02

(52) U.S. Cl. CPC H05K 1/0296
USPC 174/257

(57) ABSTRACT

A printed circuit board (PCB) includes an edge-component welded to the edge, which includes a plurality of pins. The PCB includes a base board and at least one slot set at edges of the base board. The pins are plugged into the base board through the at least one slot, the at least one slot is set right below the pins, and the position of the at least one slot is designed without copper pouring. In production, copper foil in the at least one slot is cut off, preventing the pins from touching the copper foil on the base board.

### BACKGROUND

1. Technical Field

The present disclosure relates to printed circuit boards (PCB)s, and particularly to a PCB for preventing edge-board components from being short-circuited.

2. Description of Related Art

In a PCB cutting process, the copper foil of some areas of the PCB will be exposed. As a result, pins of edge-board components welded on the PCB will short-circuit when touching the copper foil, thereby damaging the PCB.

Therefore, it is desirable to provide a PCB preventing the edge-board components from being short-circuited.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure.

FIG. 1 is a schematic view of an embodiment of a PCB preventing edge-board components from being short-circuited.

FIG. 2 is a cross-sectional view of the PCB of FIG. 1 through II-IV line.

### DETAILED DESCRIPTION

Embodiments of the present disclosure will be described with reference to the drawings.

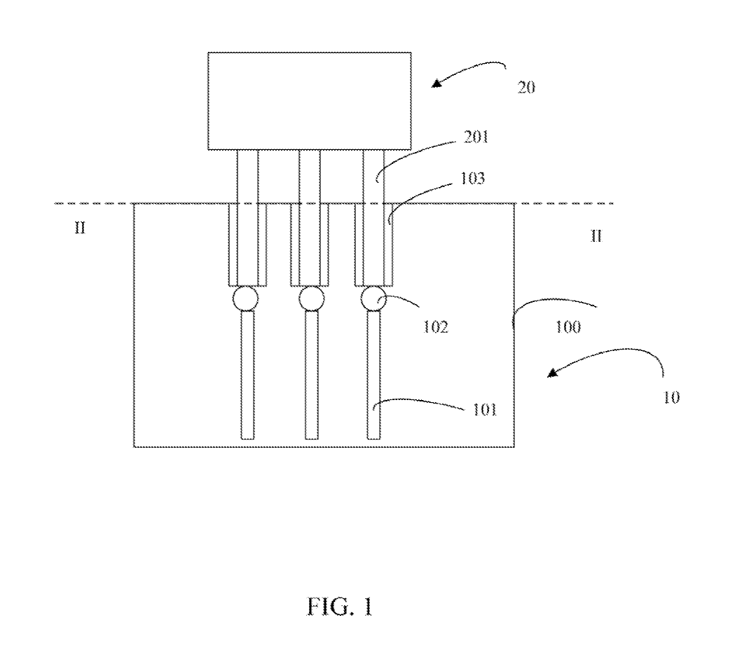

FIG. 1 is a schematic view of an embodiment of a PCB 10 preventing edge-board components from being short-circuited. The PCB 10 is welded with an edge-component 20. The edge-component 20 includes a plurality of pins 201. The PCB 10 includes a base board 100, a plurality of printed wires 101, and at least one welded point 102 which connects at least one pin 201 and at least one printed wire 101. The PCB 10 further includes at least one slot 103 which is set at the edge of the base board 100. The pins 201 are received into the base board 100 through the at least one slot 103.

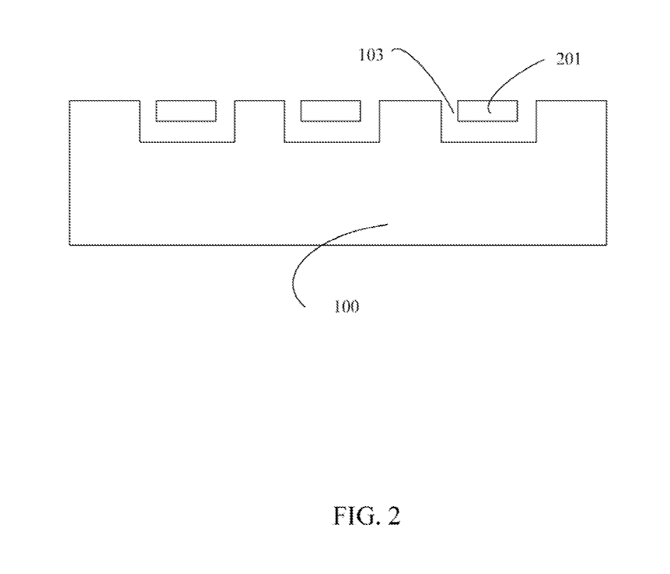

FIG. 2 is a cross-sectional view of the PCB of FIG. 1 through II-II line of the base board 100. The slots 103 are set right below the welded points 102 and the pins 201, and positions of the slots 103 on the base board 100 are designed without copper pouring. In production, copper foil in the slots 103 are cut off, preventing the pins 201 from touching the copper foil on the base board 100, thereby preventing the edge-component 20 short-circuiting from the PCB 10.

In other embodiments, the pins 201 connect with positive voltage, negative voltage, or ground. The slots 103 are not set below the pins 201 connected with ground.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A printed circuit board (PCB) welded with an edge-component, the edge-component comprises a plurality of pins, the PCB comprising:
a base board, copper foil located on a surface of the baseboard, and at least one slot defined in the surface at at least one edge of the base board,
wherein the pins are plugged into the base board through the at least one slot, the at least one slot is set right below the pins, copper foil is not present in the at least one slot, the pins do not contact the copper foil on the base board.

2. The PCB of claim 1, further comprising a plurality of printed wires and at least one welded point which connects at least one of the pins of the edge-component and at least one of the printed wires; wherein the at least one slot is also set right below the at least one welded point.

3. The PCB of claim 1, wherein the slots are not set below the pins connected with ground.
